(19) United States
(12) Patent Application Publication
(10) Pub. No.: US 2010/0013060 A1
(43) Pub. Date: Jan. 21, 2010

(54) METHOD OF FORMING A CONDUCTIVE TRENCH IN A SILICON WAFER AND SILICON WAFER COMPRISING SUCH TRENCH

(75) Inventors: Yann Pierre Roger Lamy, Eindhoven (NL); Freddy Roozeboom, Waalre (NL); Fredricus van den Heuvel, Waalre (NL)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/507,269

(22) Filed: Jul. 22, 2009

(30) Foreign Application Priority Data
Jun. 22, 2008 (EP) 08160892.9

(51) Int. Cl. H01L 23/48; H01L 21/768

(52) U.S. Cl. 257/621; 438/675; 257/E23.011; 257/E21.597

(57) ABSTRACT

A method of forming a conductive trench such as a through-silicon-via in a silicon wafer is disclosed. The method includes depositing a mask over a wafer surface; patterning the mask to expose a portion of the wafer; exposing the wafer to a first etching step in which a first portion of the trench is formed; exposing the wafer to an second etching step in which a tapered second portion of the trench is formed, where the first portion has a continuously non-increasing width from the wafer surface to the second portion; and filling the trench with a conductive material. A silicon wafer including such a conductive trench is also disclosed.

### CROSS REFERENCE

This application claims priority to European patent application number 08160892.9, filed Jul. 22, 2008, the disclosure of which is incorporated herein by reference.

### FIELD OF THE INVENTION

The present invention relates to a method of forming a conductive path through a silicon wafer, comprising depositing a mask over a wafer surface; patterning said mask to expose a portion of the wafer; and exposing the wafer to a first etching step.

The present invention further relates to a silicon wafer comprising a conductive path through the wafer.

### BACKGROUND

Ongoing trends in semiconductor device technology include miniaturization of the feature sizes of the semiconductor device as well as increasing the functional complexity of the semiconductor device. Although a feature size reduction may facilitate an increase in the number of semiconductor building blocks per unit area of a semiconductor device, e.g. a die or an integrated circuit (IC), thus facilitating more complex functionality per device, as for instance demonstrated by the system-on-chip concept, many demands for increased functional complexity cannot be met by a single device.

Recently, this has led to the development of aggregate devices such as multi-chip modules (MCMs) and system-in-packages (SiPs), in which multiple dies (or ICs) are mounted on both sides of a carrier, typically a silicon wafer, and interconnected such that when the assembly is packaged, it will behave as a single multi-component system. This way, demand for complex functionality can be better met.

However, the manufacturing of such aggregate devices is not without problems. In order to interconnect separate dies on opposite sides of the silicon wafer, the silicon wafer must be provided with conductive paths through the wafer. To this end, so-called through-silicon vias (TSVs) must be formed, which are subsequently filled with a conductive material, e.g. a metal. Such a conductive path must be low-ohmic, i.e. must have a low enough resistance to ensure that the appropriate electrical interaction between devices mounted on opposite sides of the conductive path is not jeopardized. This cannot be easily achieved, because a TSV has a very high aspect ratio, which is defined as the depth of the via through the wafer divided by the (average) width of the via. This makes it difficult to completely fill the TSV with the conductive material. Yet, such a (near-) complete fill is important because it ensures the low-ohmic nature of the conductive path through the wafer.

Unfortunately, many of the techniques used to form vias in semiconductor devices are unsuitable for the formation of TSVs. This is because the aspect ratios of TSVs are completely different, i.e. substantially larger, as well as because the TSVs are formed in a different material, i.e. silicon, whereas the vias in semiconductor devices are typically formed through insulating materials such as SiO₂.

One way of ensuring a low-ohmic fill of a TSV having substantially vertical sidewalls, is by depositing a thin film seed layer in the TSV by means of atomic layer deposition or chemical vapor deposition. The seed layer facilitates the effective filling of the TSV with the conductive material, e.g. by means of electroplating. However, the growth rate of such a seed layer in ALD and CVD processes is very low, thus leading to undesirably long processing times of the silicon wafer, thereby increasing the manufacturing cost of the wafer. Moreover, ALD and CVD processes allow very little variation in the process parameters, which makes these processes difficult to control.

For this reason, TSVs having a predominantly tapered profile have been proposed, because such TSVs can be effectively filled with a conductive material such as copper, for instance because a seed layer can be more easily formed in such a TSV. Tapered profiles can be readily achieved using an anisotropic reactive ion etch step, as for example demonstrated by Tezcan et al. in the Proceedings of the IEEE Electronics Packaging Technology Conference, 2006 pages 22-28.

Tezcan et al. use the C₄F₈ (perfluorocyclobutane) content in the etching mixture to control the slope of the sidewall. However, a problem with the use of C₄F₈ is that it passivates the silicon, thereby reducing the etch rate of the via etching process. Furthermore, a silicon overhang is formed in the via opening, which complicates the seed layer deposition and therefore the efficient filling of the via with the conductive material. The use of O₂ as passivation source to control the slope of the via sidewalls improves the etch rate, but not the negative slope part of the via. This problem has been solved by Tezcan et al. by exposing the maskless wafer to a wet or silicon dry etching step. Preferably, a dry etching step is performed because it can be performed in the same equipment as the anisotropic etching step.

A disadvantage of this approach is that it is limited to a silicon wafer that does not carry any components on the surface exposed to the maskless etching step.

### SUMMARY

An embodiment of the present invention seeks to provide a method of forming a low-ohmic conductive trench in a silicon wafer in which sensitive components on the wafer surface can also be protected.

An embodiment of the present invention further seeks to provide a silicon wafer comprising a low-ohmic conductive trench in the silicon wafer without prohibiting the presence of etch-sensitive components on the wafer surface.

According to a first aspect of the present invention, there is provided a method of forming a conductive trench in a silicon wafer, comprising depositing a mask over a wafer surface patterning said mask to expose a portion of the wafer, exposing the wafer to a first etching step in which a first portion of a trench is formed, exposing the wafer to an second etching step in which a tapered second portion of the trench is formed, the first portion having a continuously non-increasing width from the wafer surface to the second portion, and filling the trench with a conductive material.

The method of n embodiment of the present invention thus facilitates the formation of a trench such as a via through a wafer protected by a patterned mask, without the introduction of a silicon overhang over the opening of the trench, e.g. via, such that provision of a low-ohmic conductive path in or through the silicon wafer can be easily achieved without damaging any sensitive component on the wafer surface. It will be appreciated that the method of the present invention may also be applied to a silicon wafer not carrying any sensitive components on its surface.

Preferably in an embodiment, the first etching step is a more isotropic etching step such as an isotropic reactive ion etching step, i.e. a chemically controlled dry etching step, and the second etching step is an anisotropic reactive ion etching controlled step. The choice of a more isotropic etching step as the initial etching step, i.e. a step being less directional than the second etching step, has the advantage that the formation of a negative slope silicon overhang partially blocking the trench opening can be effectively avoided, whereas the subsequent more anisotropic, i.e. more directional, etching step provides the tapering of the second portion of the trench. Reactive ion etching steps are particularly suitable, and have the additional advantage that both etching steps may be performed in the same reaction chamber, thus avoiding the need to relocate the silicon wafer during the etching process.

Preferably in an embodiment, the first etching step comprises exposing the portion to a mixture of SF₆ and O₂.

Preferably in an embodiment, the second etching step comprises exposing the portion to a mixture of SF₆, O₂ and C₄F₈ (perfluorocyclobutane) in a continuous process.

The use of the above etching steps gives particularly good results in terms of tapering and aspect ratio control of the trench, such as a blind via or a TSV.

The method may further comprise exposing an intermediate trench portion to a passivation step between the first etching step and the second etching step. This ensures that the width of the intermediate trench portion is not significantly increased during the (anisotropic) second etching step, and that the risk of the introduction of a negative overhang of the trench opening during the second etching step is further reduced.

In an embodiment, the isotropic etching step comprises a plurality of isotropic etching substeps. This has the advantage that the shape of the first portion can be better controlled, such that a smoother transition between the first portion and the second portion can be obtained.

Prior to filling the trench with the conductive material, the method may further comprise depositing a liner in at least a part of the trench. Such a liner may for instance be a barrier layer or a seed layer to facilitate the filling of the trench, e.g. the deposition of a metal using a vapor deposition step or an electroplating step.

The conductive material may be selected from the group consisting of copper, titanium and aluminum. Such materials are known to be suitable materials for application in a semiconductor device manufacturing process and provide a low-ohmic through-wafer connection when the trench is effectively filled with these conductive materials.

In case of the trench being a through silicon via, such a via does not have to be formed by etching only. In an embodiment, the via formed through etching is a blind via, the method further comprising thinning the wafer to expose the blind via. Such thinning may for instance be achieved using chemical mechanical polishing (CMP) or back-grinding techniques.

According to a further aspect of an embodiment of the present invention, there is provided a silicon wafer comprising a conductive trench in the wafer, the conductive trench comprising a first portion, and a second portion having a tapered shape, the first portion having a shape different from the second portion, and having a continuously non-increasing width from the wafer surface to the second portion.

The shape of the conductive trench such as a TSV filled with the conductive material ensures that the path is of a good quality and low-ohmic, because the presence of any negative overhang of the trench opening filled to form the conductive path has been avoided.

The silicon wafer may further comprise a thin film such as a barrier layer between at least a part of the conductive trench and the silicon wafer.

The silicon wafer of an embodiment of the present invention may be used for the formation of a device comprising a first semiconductor device mounted on a first surface of the silicon wafer, a second semiconductor device mounted on an opposite surface of the silicon wafer, the first semiconductor device and the second semiconductor device being conductively connected through the conductive via. Such a device, which for instance may be a system-in-package, benefits from the good quality conductive path through the silicon wafer because the electrical interaction, e.g. signal communication, between the first semiconductor device and the second semiconductor device is unlikely to fail.

### BRIEF DESCRIPTION OF THE EMBODIMENTS

Embodiments of the invention are described in more detail and by way of non-limiting examples with reference to the accompanying drawings, wherein

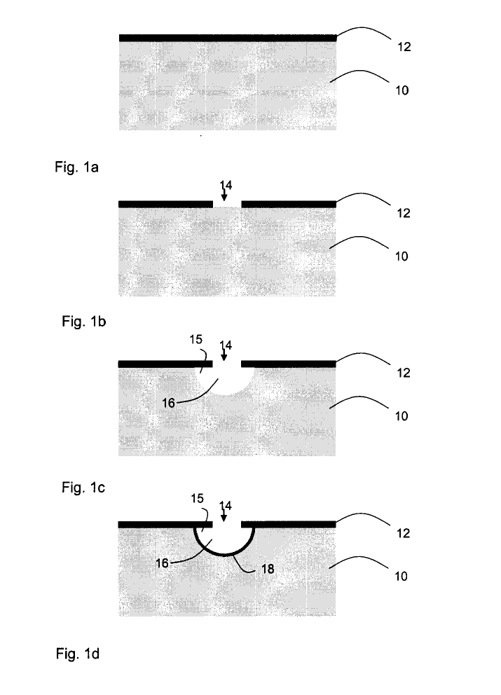

FIGS. 1a-j depict various embodiments of the method of the present invention;

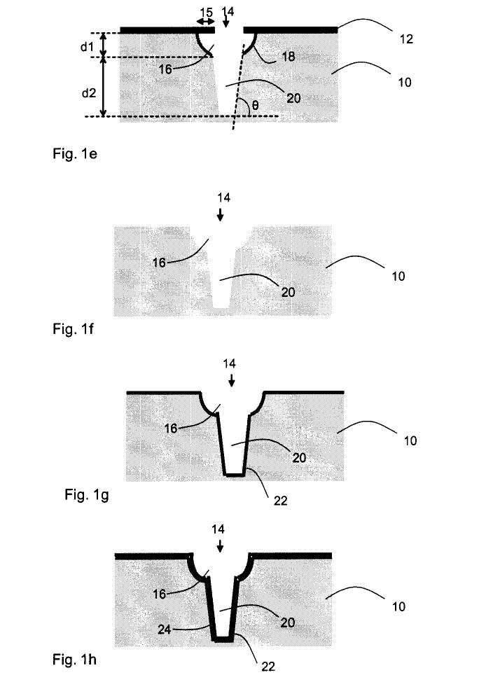

FIG. 2 depicts scanning electron microscope (SEM) images of a wafer comprising a blind via in accordance with an embodiment of the present invention;

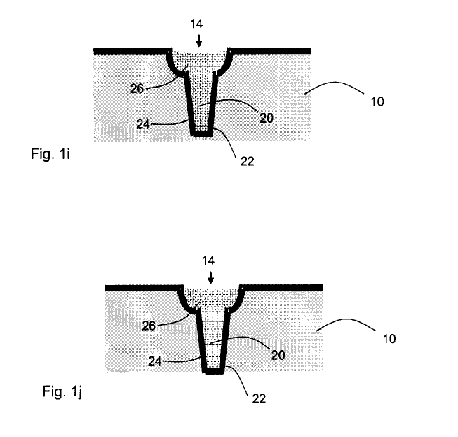

FIG. 3 depicts optical microscope images of a wafer comprising a blind via in accordance with an embodiment of the present invention;

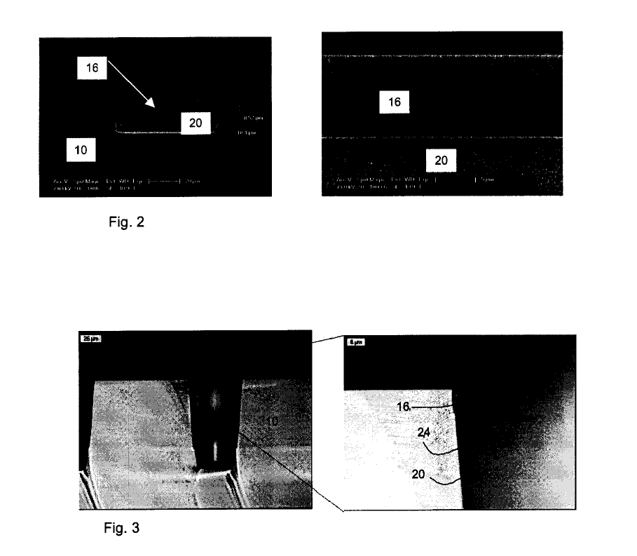

FIG. 4 depicts a SEM image of a wafer comprising a filled via in accordance with an embodiment of the present invention; and

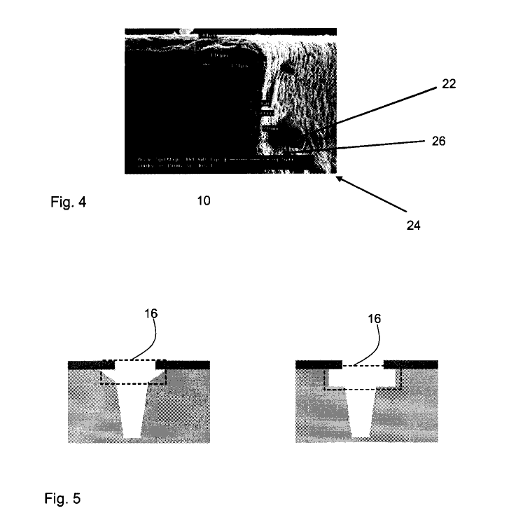

FIG. 5 depicts alternative embodiments of an aspect of the method of the present invention.

### DETAILED DESCRIPTION OF THE DRAWINGS

It should be understood that the Figures are merely schematic and are not drawn to scale. It should also be understood that the same reference numerals are used throughout the Figures to indicate the same or similar parts.

FIG. 1a depicts a silicon wafer 10 covered by a mask layer 12. The mask layer 12 may be any suitable etch resist layer, e.g. a hard mask layer such as a SiO₂ layer, and may be deposited using any suitable technique, e.g. PVD, CVD or ALD. The mask layer 12 may be deposited over the surface of the silicon wafer 10 to protect one or more semiconductor devices or other sensitive components at the surface of the silicon wafer 10 from exposure to subsequent etching steps that may damage these components. It is emphasized that the presence of such etch-sensitive components at the surface of the silicon wafer 10 is, however, not essential to the present invention.

In a next step, shown in FIG. 1b, the mask layer 12 is patterned such that one or more portions 14 of the surface of the silicon wafer 10 are exposed. The locations of the one or more portions 14 are chosen in accordance with the required locations of one or more conductive regions in or through the silicon wafer 10, such as a blind via or a through via filled with a conductive material, as will be discussed in more detail later. The patterning of the mask layer may be done in any suitable way, e.g. by the selective deposition of a photoresist layer such as Novolac™, and a subsequent lithography step. Other examples will be readily available to the skilled person, and will not be discussed in further detail for reasons of brevity only.

Next, the silicon wafer 10 is exposed to a first etching step, which is predominantly isotropic in nature, such that a first portion 16 of a trench in the silicon wafer 10 is formed. This is shown in FIG. 1c. Due to the predominantly isotropic nature of the first etching step, the first portion 16 does not have any bottlenecks or overhangs in the vicinity of the surface of the silicon wafer 10. In other words, the width of the first portion 16 is continually non-increasing from the surface of the silicon wafer 10 downwards. In FIG. 1c, the first portion 16 has a continually decreasing width from the surface of the silicon wafer 10 downwards.

Also, the predominantly isotropic nature of the first etching step causes the formation of an undercut 15 under the masking layer 12. In other words, the masking layer 12 partially overhangs the first portion 16. Non-limiting examples of the first etching step will be discussed in more detail later.

In accordance with the present invention, the silicon wafer 10 is to be exposed to a second etching step under different etching conditions, i.e. anisotropic etch conditions. It may be desirable to protect the first portion 16 of the trench to be protected from further etching, e.g. to limit the width of the first portion 16, since the width, i.e. the horizontal dimension of the first portion 16, is directly related to the number of trenches that can be formed in the silicon wafer 10, and an excessive width of the first portion 16 will unduly limit this number. In case such protection is indeed desirable, the first portion 16 may be exposed to an optional passivation treatment, in which a passivation layer 18 is formed on the surface of the portion 16. This is shown in FIG. 1d. Any suitable passivation agent may be used, such as C₄F₈, which is a particularly suitable agent for passivating the Si surface of the first portion 16.

After the first etching step and the optional passivation step, the silicon wafer 10 is exposed to a second etching step which is anisotropic in nature such that a tapered second portion 20 having a depth d2 of the trench in the wafer is formed. In a preferred embodiment, the anisotropic etching step is executed by means of a reactive ion etching step, and the first etching step forming the first portion 16 of the trench is performed by means of an isotropic reactive ion etching (RIE) step to a depth d1, such that both steps can be executed in the same reaction chamber. The use of the combination of at least one isotropic RIE step and an anisotropic RIE step also facilitates the formation of trenches, e.g. vias, in the wafer in a wide range of widths, e.g. 10-100 micron.

The isotropic RIE step may comprise the application of a mixture of an etching gas and a passivation gas, such as SF₆ and O₂, whereas the anisotropic RIE step may comprise the application of a etching gas and a passivation gas in different ratios, such as a mixture of SF₆, C₄F₈ and O₂. The increased ratio of the passivation gases such as O₂ and C₄F₈ increases the anisotropicity of the RIE step. The presence of the C₄F₈ improves the wall smoothness of the second portion 20.

The anisotropy of the RIE etching step may further be controlled by the application of a bias voltage to the chuck (not shown) supporting the silicon wafer 10 in the reaction chamber. This bias voltage is also referred to as platen power in the art. An increase in this bias voltage increases the anisotropy of the etching step because it promotes the ion-assisted nature of the etching process. Hence, during the first etch, which preferably is highly isotropic in nature, the bias voltage is kept relatively low to suppress the ion-assisted component of the etching process, such that the etching process is substantially chemically assisted. In the anisotropic etching step to form the tapered portion 20, the bias voltage is increased to increase the ion-assisted nature of the second etching step. The competition between the ion-assisted process and the chemical process provides the tapered shape of the second portion 20.

The tapering angle θ of the second portion may be varied by variation of the fraction of the passivation gases in the anisotropic etch reaction mixture. Preferably, the fraction C₄F₈ is kept as small as possible, because C₄F₈ is an effective passivating agent for silicon, which means that the reaction times deteriorate, i.e. substantially increase, with the increase of the C₄F₈ fraction. Hence, it is preferred that the amount of O₂ in the anisotropic etch reaction mixture is increased.

Although O₂ also acts as a passivating agent by means of surface oxidation of the silicon, it has been found that when the anisotropic etching step is performed in a sufficiently elevated temperature range, e.g. 20-30° C., this oxidation process is sufficiently suppressed. It is currently believed that this is because at these temperatures, the O₂ cannot effectively stick to the exposed silicon side walls. This has the further advantage that the cavity (via) surface is kept smooth because the formation of silicon oxide on the cavity walls is reduced. This facilitates the efficient formation of liners on the cavity surface, which typically require a substantially smooth surface to achieve a good lining coverage of the surface.

Table I gives a non-limiting example of the process condition windows for the isotropic etch step (left column), the passivation step (middle column) and the anisotropic etch step (right column) in an ICP™ STS Advanced Silicon Etcher.

TABLE I

| | Isotropic etch | Passivation | Anisotropic etch |
|---|---|---|---|
| SF₆ (sccm)¹ | 200 | 0 | 70-90 |
| O₂ (sccm) | 5-20 | 0 | 80-60 |
| C₄F₈ (sccm) | 0 | 120 | 5 |
| Pressure (Torr) | 8*10⁻² | 8*10⁻² | 3-4*10⁻² |
| Etch time (min) | 1-5 | 0.5-1 | 30-60 |
| Temperature (° C.) | 10 | 10 | 20-30 |
| Power coil (W) | 2000 | 800 | 2000 |
| Power platen (W) | 0 | 0 | 20 |

| | |
|---|---|
| Aspect ratio | 2-5 |
| θ (°) | 70-85 |
| Etch rate (μm/min) | 5-7 |

¹standard cubic centimeter per minute

It is noted that the high O₂ content in the anisotropic RIE step ensures that a much higher etch rate compared to prior art techniques is achieved, due to the fact that over-passivation of the silicon sidewalls of the intermediate trench structure is avoided. This is for instance because the ratio of C₄F₈ in the reaction mixture has been kept small.

With respect to the undercut 15, the dimensions of this undercut may be varied by variation of the duration of the first etching step. An increase in the duration of this step will increase the lateral dimensions of the undercut.

It is preferred that the slope angle θ of the tapered portion 20 is chosen in a range of 70-85° because this ensures that a complete coverage of the walls of the trench can be achieved using deposition techniques such as physical vapor deposition (PVD), which has the advantage that the trench can be lined more quickly compared to techniques such as CVD and ALD. It is emphasized that the use of PVD techniques is by no means trivial in the field of TSVs because the large aspect ratios of such vias typically prohibits the full coverage of the via surface when using PVD. The angle θ may be varied by variation of the O₂ and/or C₄F₈ ratio in the reaction mixture of the anisotropic etch step.

An important aspect of the present invention is that it facilitates the formation of a tapered trench portion having a relatively smooth surface despite the use of a high O₂ content in the anisotropic etch reaction mixture. This is demonstrated in FIG. 2, in which a cross section SEM image of a cavity in a silicon wafer as formed by the method of the present invention is shown. The left pane shows the cavity after 5 minutes anisotropic etching with a 50% O₂ ratio. The right pane is a magnification of the side wall of the tapered portion 20 shown in the left pane, which shows a fine nanomesh-like granular structure indicative of the smoothness of the surface of the tapered portion 20. This smooth surface is achieved by combining the high O₂ content in the etching reagent mixture with a reaction temperature of at least 20° C., as previously explained. The effect of a passivation layer 18 is clearly seen, since the first etch cavity remains un-etched by the second anisotropic etch.

Now, upon returning to FIG. 1e, it is emphasized that the cavity formed by the method of the present invention may for instance be a via. In FIG. 1e, the via is a blind via by way of non-limiting example only. Alternatively, the duration of the anisotropic etching step may be extended such that the second portion 20 reaches the bottom of the silicon wafer 10, such that the cavity formed by the first portion 16 and the second portion 20 extends through the whole silicon wafer.

At this point, it is emphasized that the first etching step of the method of the present invention does not need to be an isotropic RIE step. Any etching step that avoids the formation of an overhang in the first portion 16 may be used. Non-limiting examples of alternative etching steps include wet etching steps such as a KOH/TMAH etching step.

After etching, the hard mask layer 12 is removed in order to allow the lining and the filing of the formed via. This can for instance be done by any conventional wet etching, e.g. buffered HF if the hard mask is a SiO₂ mask, or microstrip if the mask is a photoresist mask, without damaging any other devices on the front side of the wafer. The via can be also cleaned by conventional wet cleaning recipes (e.g. Piranha, Microstrip) to remove polymers residues after silicon etching. The passivation layer 18 of cavity 16 is removed in this cleaning process. This optional step is shown in FIG. 1f. In subsequent steps of the method, one or more liners may be deposited in the cavity of FIG. 1f. For instance, an insulation layer 22 may be deposited in the cavity to insulate the silicon wafer 10 from a conductive material to be deposited in the cavity. This is shown in FIG. 1g. Such an insulation layer may be any suitable insulating layer and may be grown in any suitable way, e.g. by means of ALD, PVD, CVD, electroless deposition or combinations thereof. The deposition of the one or more liners may further comprise the deposition of a seed layer on the insulated surface of the cavity or on an earlier deposited optional barrier layer such as a TiN of TaN barrier layer for preventing metal diffusion contamination, e.g. Cu contamination, into the silicon. This is depicted in FIG. 1h.

Such a seed layer 24 may be a layer of the conductive material to be formed in the cavity, such as a Cu, Al, W or Ti layer or combinations thereof. Such layers may be formed in a PVD step because of the tapered nature of the second portion 20 of the cavity and the absence of a negative slope, i.e. overhang in the first portion 16 of the cavity, which means that the inner surface of the cavity can be fully covered using a PVD step. Other layers, e.g. insulating layers may also be deposited using PVD sputtering.

An example of a cavity lined with a copper seed layer deposited by means of PVD sputtering in shown in FIG. 3, which depicts optical microscope pictures of a tapered silicon via with an aspect ratio of around 5. The via is etched in Si in accordance with the method of the present invention having an initial width of 50 μm. The isotropic etching of the first portion 16 has been used to minimize the undercut 15 and to match the tapered second portion 20. A thin film 24 of copper can be deposited by PVD as can be observed in the right pane.

Upon returning to FIG. 1, the cavity may subsequently be filled with the conductive material 26 as shown in FIG. 1n. The conductive material 26 preferably is a metal selected from the group consisting of Al, W, Ti and Cu because these metals can be readily applied in existing semiconductor manufacturing processes. However, it should be understood that other conductive materials such as other metals or metal alloys may also be used to provide a low-ohmic conductive trench in the silicon wafer 10. The cavity 26 may be filled with the conductive material in any suitable way, e.g. by means of electroplating.

In the context of the present invention, a low-ohmic material has a resistivity of less than 100 μΩ.cm. Preferably, the conductive material has a resistivity of less than 10 μΩ.cm. More preferably, the conductive material has a resistivity of less than 2.5 μΩ.cm, which makes the conductive trench suitable for application in high frequency application domains such as RF devices.

FIG. 4 depicts a SEM picture of the tapered silicon via of FIG. 3 after lining the via with a conductive material 2, which is copper in this example. It is clear from this image that a homogeneous lining is achieved, thus providing a conductive layer appropriate for electroplating.

Upon returning to FIG. 1, it should be appreciated that the method of the present invention may comprise several alternative embodiments. A first alternative embodiment is shown in FIG. 1j, in which the silicon wafer 10 is thinned to expose the bottom of the trench. This is for instance advantageous when the trench is a blind via. The thinning may be achieved in any suitable way, e.g. by back side-grinding. In FIG. 1j, the thinning of the silicon wafer 10 is performed after the trench is filled with the conductive material 26. However, it will be understood that this thinning step may be inserted at another point of the process flow, e.g. before the filling of the trench with the conductive material 26 or even before lining the trench with one or more a thin film layers.

In FIG. 1j, this step is performed after the trench is filled with the conductive material 26. However, it will be understood that this thinning step may be inserted at another point of the process flow, e.g. before the filling of the trench with the conductive material 26 or even before lining the trench with one or more a thin film layers.

Although it is preferred that the first portion 16 is formed using an isotropic RIE step as previously explained, which leads to a bowl-shaped first portion 16 as shown in e.g. FIG. 1c, other shapes of the first portion 16 may also be considered, as demonstrated in FIG. 5, where a triangular shaped first portion 16 and a rectangular shaped first portion 16 are shown. Such shapes may be achieved by choosing different first etching processes such as the alternative wet etching steps previously discussed.

The conductive trench formed by the method of the present invention may be advantageously used in System-in-Package modules to connect chips one above each other. However, it should be understood that the application of the present invention is not limited to SiPs. Alternatively, this kind of trench, e.g. a tapered via, can also find further application in microfluidics, thermal dissipation, microbatteries and so on.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

1. A method of forming a conductive trench in a silicon wafer, comprising:
depositing a mask over a wafer surface;
patterning the mask to expose a portion of the wafer;
exposing the wafer to a first etching step in which a first portion of the trench is formed;
exposing the wafer to an second etching step in which a tapered second portion of the trench is formed, wherein the first portion has a continuously non-increasing width from the wafer surface to the second portion; and
filling the trench with a conductive material.

2. The method according to claim 1, wherein the conductive trench is a via.

3. The method according to claim 1, wherein the first etching step is an isotropic reactive ion etching step and the second etching step is an anisotropic reactive ion etching step.

4. The method according to claim 3, wherein the isotropic etching step comprises a plurality of isotropic etching substeps.

5. The method according to claim 1, further comprising depositing at least one layer selected from the group consisting of an insulating layer and a seed layer in the trench prior to filling the trench with the conductive material.

6. The method according to claim 1, wherein the conductive material is selected from the group consisting of copper, titanium and aluminum.

7. The method according to claim 1, further comprising exposing the first trench portion to a passivation step between the first etching step and the second etching step.

8. The method according to claim 3, wherein the isotropic etching step comprises exposing the portion of the wafer to a mixture of SF₆ and O₂.

9. The method according to claim 3, wherein the anisotropic reactive ion etching step comprises exposing the portion of the wafer to a mixture of SF₆, O₂ and C₄F₈.

10. The method according to claim 2, wherein the via is a blind via, the method further comprising thinning the wafer to expose the blind via.

11. A silicon wafer comprising a conductive trench, the conductive trench comprising:
a first portion; and
a second portion having a tapered shape, wherein the first portion has a different shape than the second portion, and has a continuously non-increasing width from a wafer surface to the second portion.

12. The silicon wafer according to claim 11, wherein the conductive trench is a via extending through the silicon wafer.

13. The semiconductor body or a silicon wafer according to claim 11, further comprising an insulating layer between the conductive trench and the silicon wafer.

14. A device comprising:
a silicon wafer including a via extending through the silicon wafer, wherein the via includes a first portion and a second portion having a tapered shape, wherein the first portion has a different shape than the second portion, and has a continuously non-increasing width from a wafer surface to the second portion;
a first semiconductor device mounted on a first surface of the silicon wafer; and
a second semiconductor device mounted on an opposite surface of the silicon wafer, the first semiconductor device and the second semiconductor device being conductively connected through the via.

15. The device according to claim 14, wherein the silicon wafer, the first semiconductor device and the second semiconductor device are part of a system in package.
